(19) United States
(12) Patent Application Publication
(10) Pub. No.: US 2002/0089023 A1
(43) Pub. Date: Jul. 11, 2002

(54) Low leakage current metal oxide-nitrides and method of fabricating same

(75) Inventors: Zhiyi Yu, Gilbert, AZ (US); Ravindranath Droopad, Chandler, AZ (US); Corey Overgaard, Phoenix, AZ (US); John Leonard Edwards JR., Phoenix, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Motorola, Inc.

(21) Appl. No.: 09/755,691

(22) Filed: Jan. 5, 2001

(51) Int. Cl. H01L 29/94; H01L 29/76; H01L 31/062; H01L 23/58; H01L 21/336; H01L 21/31; H01L 21/469

(52) U.S. Cl. 257/411; 257/325; 257/639; 257/649; 257/295; 257/310; 438/287; 438/285; 438/785

(57) ABSTRACT

A structure and method for forming a high dielectric constant device structure includes a monocrystalline semiconductor substrate and an insulating layer formed of a metal oxide-nitride such as MₙOₘ₋ₓNₓ, wherein M is a metallic or semi-metallic element or combination of metallic and/or semi-metallic elements and m and n are integers. Semiconductor devices formed in accordance with the present invention exhibit low leakage current density and improved chemical, thermal, and electrical stability over conventional metal oxides.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include an epitaxially grown, high dielectric constant oxide-nitride to reduce leakage current density.

### BACKGROUND OF THE INVENTION

Epitaxial growth of single crystal oxide thin films on silicon is of great interest in numerous device applications, such as, for example, ferroelectric devices, high density memory devices, and next-generation MOS devices. Also, in the preparation of these films, it is pivotal to establish an ordered transition layer or buffer layer on the silicon surface for the subsequent growth of the single crystal oxides, such as, for example, perovskites.

Some of these single crystal oxides, such as BaO and BaTiO₃, are formed on silicon (100) using a BaSi₂ (cubic) template by depositing one fourth monolayer of Ba on silicon (100) using molecular beam epitaxy at temperatures greater than 850° C. See, e.g., R. McKee et al., Appl. Phys. Lett. 59(7), p. 782-784 (Aug. 12, 1991); R. McKee et al., Appl. Phys. Lett. 63(20), p. 2818-2820 (Nov. 15, 1993); R. McKee et al., Mat. Res. Soc. Symp. Proc., Vol. 21, p. 131-135 (1991); U.S. Pat. No. 5,225,031, issued Jul. 6, 1993, entitled “PROCESS FOR DEPOSITING AN OXIDE EPITAXIALLY ONTO A SILICON SUBSTRATE AND STRUCTURES PREPARED WITH THE PROCESS”; and U.S. Pat. No. 5,482,003, issued Jan. 9, 1996, entitled “PROCESS FOR DEPOSITING EPITAXIAL ALKALINE EARTH OXIDE ONTO A SUBSTRATE AND STRUCTURES PREPARED WITH THE PROCESS.” A strontium silicide (SrSi₂) interface model with a c(4×2) structure has also been proposed. See, e.g., R. McKee et al., Phys. Rev. Lett. 81(14), 3014 (Oct. 5, 1998). Atomic level simulation of this proposed structure, however, indicates that it is not likely to be stable at elevated temperatures.

Growth of SrTiO₃ on silicon (100) using an SrO buffer layer has been accomplished. See, e.g., T. Tambo et al., Jpn. J. Appl. Phys., Vol. 37, p. 4454-4459 (1998). However, the SrO buffer layer was relatively thick (100 Å), thereby limiting its application for transistor films; moreover, crystallinity was not maintained throughout the growth process.

Furthermore, SrTiO₃ has been grown on silicon using thick oxide layers (60-120 Å) of SrO or TiO. See, e.g., B. K. Moon et al., Jpn. J Appl. Phys., Vol. 33, p. 1472-1477 (1994). The thickness of these buffer layers, however, would limit their application for transistors.

In CMOS applications, these types of oxide layers are fabricated using molecular oxygen and are formed thin (i.e., less than 50 Å), resulting in leaky films in which high electrical leakage is experienced due to oxygen deficiencies or vacancies. Furthermore, these films require a post-growth anneal in oxygen to reduce leakage current density across the oxide layer.

Accordingly, a need exists for a method for fabricating a high dielectric constant oxide on a semiconductor structure having low leakage current density.

It is a purpose of the present invention to provide for a method of fabricating a high dielectric constant oxide-nitride on a semiconductor structure having low leakage current density.

It is a further purpose of the present invention to provide for a method of fabricating a high dielectric constant oxide-nitride on a semiconductor structure in which the gate dielectric leakage current density is near zero.

It is another purpose of the present invention to provide for a method of fabricating a semiconductor device structure using a high dielectric constant oxide-nitride such as MₙOₘ₋ₓNₓ (x<m), wherein M is a metallic or semi-metallic element or combination of metallic and/or semi-metallic elements.

### BRIEF DESCRIPTION OF THE DRAWINGS

The present invention is illustrated by way of example and not limitation in the accompanying figures, in which like references indicate similar elements, and in which:

FIG. 1 illustrates schematically, in cross section, a semiconductor structure fabricated in accordance with one embodiment of the present invention;

FIG. 2 illustrates schematically, in cross section, a semiconductor device structure fabricated in accordance with an alternative embodiment of the present invention;

FIG. 3 illustrates schematically, in cross section, a semiconductor device structure fabricated in accordance with a further embodiment of the present invention;

FIG. 4 illustrates schematically, in cross section, a MOS device structure in accordance with a further embodiment of the present invention; and

FIG. 5 illustrates schematically, in cross section, a MOS device structure in accordance with yet another embodiment of the present invention.

Skilled artisans will appreciate that elements in the figures are illustrated for simplicity and clarity and have not necessarily been drawn to scale. For example, the dimensions of some of the elements in the figures may be exaggerated relative to other elements to improve understanding of the various embodiments of the present invention.

### DETAILED DESCRIPTION OF THE DRAWINGS

The present invention provides a method of fabricating a high dielectric constant insulating layer on a semiconductor structure using a high dielectric constant oxide-nitride such as MₙOₘ₋ₓNₓ (x<m), wherein M is a metallic or semi-metallic element or combination of metallic and/or semi-metallic elements. In one aspect of the invention, the metal oxide-nitride is crystalline and maintains a cubic structure with a lattice constant very close to the lattice constant of a variety of common materials, such as, for example, Si, Ge, SiGe, GaAs, and InP, and can be fabricated epitaxially by PVD, CVD, MOCVD, ALE, MEE, CSD, PLD, or MBE, even under low process gas pressures. With nitrogen incorporated into the insulating oxide layer, the leakage current density can be significantly lower than in insulating oxide layers that do not incorporate nitrogen.

In a further aspect of the present invention, the oxide-nitrides used as insulating layers also serve as inter-diffusion barriers and are more stable against thermal, chemical, and resistance degradation as compared to conventional oxides, such as, for example, SrTiO₃ For these reasons, the oxide-nitrides disclosed in accordance with the present invention are attractive candidates for MOSFET high dielectric constant gate dielectric and high-voltage capacitor applications.

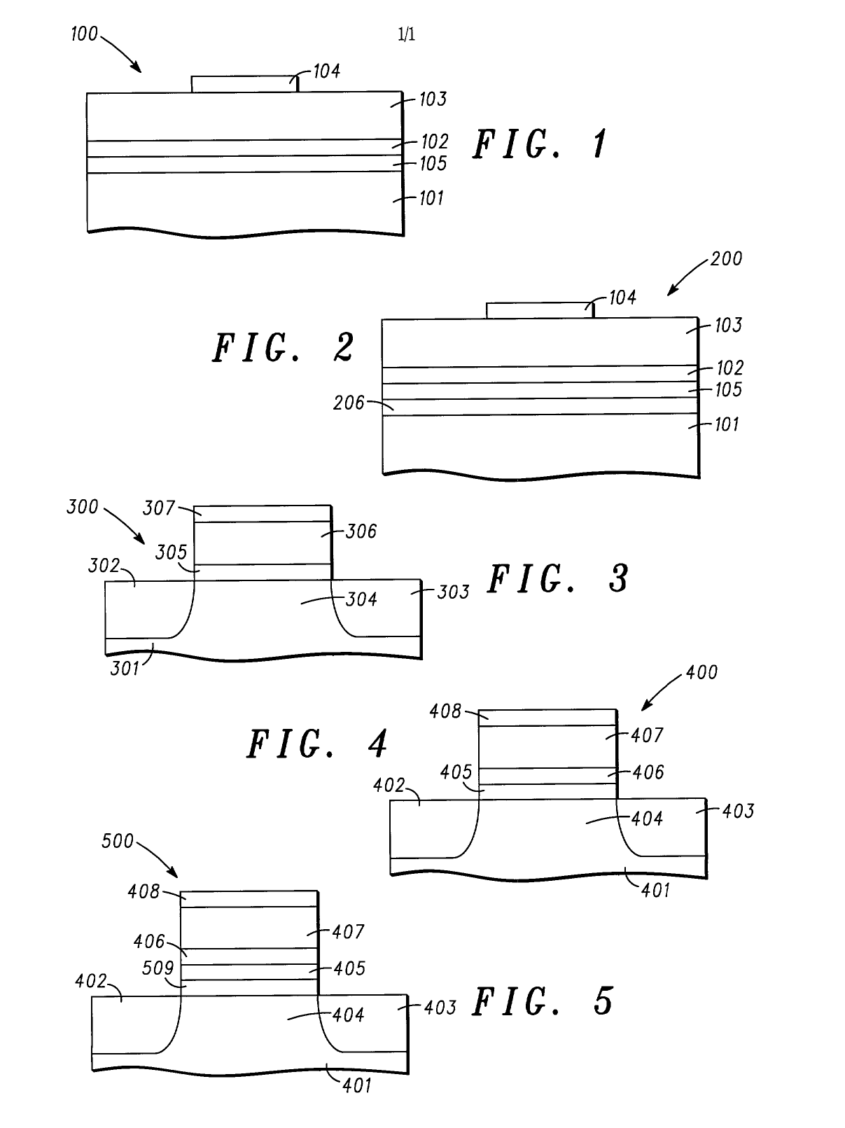

FIG. 1 illustrates schematically, in cross section, a structure 100 in accordance with an exemplary embodiment of the present invention. Structure 100 may be a device such as, for example, a component for a MOS device or any high dielectric constant device. Structure 100 includes a monocrystalline semiconductor substrate 101. Substrate 101 may comprise any suitable monocrystalline semiconductor material, such as, for example, silicon (Si), germanium (Ge), silicon germanium (Si—Ge), indium phosphide (InP), or gallium arsenide (GaAs). Substrate 101 may also comprise a suitable compound semiconductor material, such as, for example, indium gallium arsenide (InGaAs), indium aluminum arsenide (InAlAs), aluminum gallium arsenide (AlGaAs), indium gallium phosphide (InGaP), and other compound semiconductor materials known to those skilled in the art to be suitable for particular semiconductor device applications. In one embodiment, substrate 101 comprises a monocrystalline silicon wafer. Substrate 101 may optionally include a plurality of material layers such that the composite substrate may be tailored to the quality, performance, and manufacturing requirements of a variety of semiconductor device applications.

A monocrystalline oxide transition layer 102 is optionally formed overlying substrate 101. Monocrystalline oxide transition layer 102, when present, may comprise a monocrystalline oxide material selected for its crystalline (i.e., lattice) compatibility with the underlying substrate as well as with any adjacent overlying material layers. In an exemplary embodiment, layer 102 may comprise an alkaline earth metal titanate, such as, for example, barium titanate (BaTiO₃), strontium titanate (SrTiO₃), or barium strontium titanate (Sr_{z}Ba_{1-z}TiO₃, 0<z<1), or another suitable oxide material, such as, for example, LaAlO₃ or SrZrO₃. In one embodiment, layer 102 is a layer of SrTiO₃ having a thickness of up to about 1 nm.

Prior to forming layer 102 or any subsequent layer, a template layer 105 may be formed overlying substrate 101. Template layer 105 may include 1-10 monolayers of oxygen, and an alkaline earth metal element suitable to successfully grow layer 102. Alternatively, template layer 105 may include 1-10 monolayers of oxygen, nitrogen, and an alkaline earth metal element suitable to successfully grow layer 102. For example, if layer 102 is formed of SrTiO₃, a suitable template layer may be Si—O—Sr or Sr—Si—O—N.

In the embodiment of the invention illustrated in FIG. 1, a monocrystalline oxide-nitride insulating layer 103 is formed overlying transition layer 102. If transition layer 102 is not present, insulating layer 103 may be formed overlying template layer 105. Layer 103 is formed by substitutionally incorporating nitrogen into a monocrystalline oxide, such as an alkaline earth metal titanate, during formation of the insulating layer. For example, during a molecular beam epitaxy growth process of SrTiO₃ or BaTiO₃ thin films on a silicon substrate, an additional nitrogen source can be introduced simultaneously with the Sr, Ba, Ti, and oxidant sources during epitaxial growth of the layer. In one embodiment, a suitable nitrogen source may be NH₃ or N₂ and/or their radicals generated by, for example, radio frequency (rf) or electron cyclotron resonance (ECR) plasma sources. The amount of nitrogen incorporated into the oxide may be chosen such that the leakage current in the oxide film is minimized.

In an exemplary embodiment, layer 103 is formed by epitaxially growing, by a process of molecular beam epitaxy, a layer of MₙOₘ₋ₓNₓ (x<m), wherein M is a metallic or semi-metallic element or combination of metallic and/or semi-metallic elements, such as, for example, strontium (Sr), titanium (Ti), barium (Ba), aluminum (Al), erbium (Er), calcium (Ca), magnesium (Mg), tantalum (Ta), bismuth (Bi), gadolinium (Gd), zirconium (Zr), hafnium (Hf), yttrium (Y), ruthenium (Ru), lanthanum (La), gallium (Ga), indium (In), lithium (Li), sodium (Na), potassium (K), rubidium (Rb), cesium (Cs), beryllium (Be), scandium (Sc), vanadium (V), niobium (Nb), chromium (Cr), molybdenum (Mo), tungsten (W), manganese (Mn), technetium (Tc), rhenium (Re), iron (Fe), cobalt (Co), rhodium (Rh), iridium (Ir), copper (Cu), silver (Ag), gold (Au), zinc (Zn), cadmium (Cd), mercury (Hg), thallium (TI), tin (Sn), lead (Pb), antimony (Sb), bismuth (Bi), cerium (Ce), praseodymium (Pr), neodymium (Nd), samarium (Sm), europium (Eu), terbium (Tb), dysprosium (Dy), holmium (Ho), thulium (Tm), protactinium (Pa), or uranium (U).

By way of example and without limitation, exemplary materials for insulating layer 103 include the following: MO₁₋ₓNₓ (x<1), such as, for example, BaO₁₋ₓNₓ, SrO₁₋ₓNₓ, MgO₁₋ₓNₓ, CaO₁₋ₓNₓ, ZnO₁₋ₓNₓ, CdO₁₋ₓNₓ, PbO₁₋ₓNₓ, BeO₁₋ₓNₓ, and combinations thereof; MO₂₋ₓNₓ (x<2), such as, for example, ZrO₂₋ₓNₓ, TiO₂₋ₓNₓ, HfO₂₋ₓNₓ, CeO₂₋ₓNₓ, SnO₂₋ₓNₓ, PrO₂₋ₓNₓ, RuO₂₋ₓNₓ, ThO₂₋ₓNₓ, and combinations thereof; M₂O₃₋ₓNₓ (x<3), such as, for example, Al₂O₃₋ₓNₓ, Ga₂O₃₋ₓNₓ, In₂O₃₋ₓNₓ, Y₂O₃₋ₓNₓ, La₂O₃₋ₓNₓ, Sc₂O₃₋ₓNₓ, Fe₂O₃₋ₓNₓ, Gd₂O₃₋ₓNₓ, Sn₂O₃₋ₓNₓ, Bi₂O₃₋ₓNₓ, Fe₂O₃₋ₓNₓ, Pr₂O₃₋ₓNₓ, Dy₂O₃₋ₓNₓ, Ho₂O₃₋ₓNₓ, and combinations thereof; M₃O₄₋ₓNₓ (x<4), such as, for example, Fe₃O₄₋ₓNₓ, Mn₃O₄₋ₓNₓ, and combinations thereof; and M₂O₅₋ₓNₓ (x<5), such as, for example, Ta₂O₅₋ₓNₓ, Nb₂O₅₋ₓNₓ, Sb₂O₅₋ₓNₓ, and combinations thereof. Furthermore, exemplary oxide-nitride materials for insulating layer 103 may be represented empirically by the formula A₍ₙ₊₁₎BₙO₍₃ₙ₊₁₎₋ₓNₓ, wherein n is an integer and A and B are metallic and/or semi-metallic elements such as those listed above in connection with M. Such materials may include, for example: SrTiO₃₋ₓNₓ, SrZrO₃₋ₓNₓ, LaAlO₃₋ₓNₓ, and combinations thereof, wherein 0<x<3; or Sr₂TiO₄₋ₓNₓ, Sr₂ZrO₄₋ₓNₓ, La₂AlO₄₋ₓNₓ, Al₂MgO₄₋ₓNₓ, and combinations thereof, wherein 0<x<4. Alternatively, insulating layer 103 may comprise (Ba,Sr)Laₙ(Sc,Al)ₙO₍₃ₙ₊₁₎₋ₓNₓ, wherein n is an integer and x<(3n+1).

The concentration of nitrogen in layer 103 may be chosen such that the leakage current in the monocrystalline oxide film is minimized, or otherwise selected in accordance with the quality, performance, and/or manufacturing requirements of the device. In an exemplary embodiment, the concentration of nitrogen incorporated into insulating layer 103 may range from greater than 0 up to about 50 atomic percent of the total concentration of oxygen and nitrogen (i.e., x≦(m−x)). Stated another way, with regard to materials represented by the formula MₙOₘ₋ₓNₓ, it is generally preferred that the ratio (m−x):x have a value greater than or equal to about 1:1. Various relative concentrations of metal, oxygen, and nitrogen in layer 103 may be achieved by establishing different flux rates for each of the materials during epitaxial growth of the monocrystalline oxide-nitride layer. Moreover, the thickness of layer 103 may vary widely according to the desired application of the semiconductor device, but is generally in the range of about 5 to 100 nm.

In FIG. 1, insofar as layers 102 and 103 may comprise a gate dielectric for a high dielectric constant semiconductor device, a conductive gate electrode 104 may be formed overlying layer 103 in accordance with techniques well known to those skilled in the art. Electrode 104 may be formed of any suitable conductive material, such as, for example, platinum.

The following example illustrates a process, in accordance with one embodiment of the invention, for fabricating a semiconductor structure having a low leakage current density.

The process starts by providing a monocrystalline semiconductor substrate comprising, for example, silicon and/or germanium. In accordance with one embodiment of the invention, the semiconductor substrate is a silicon wafer having a (100) orientation. The substrate may be oriented on axis or, at most, in the range of about 0.5° off axis. At least a portion of the semiconductor substrate has a bare surface, although other portions of the substrate, as described below, may encompass other structures. The term “bare” in this context means that the surface in the bare portion of the substrate has been cleaned to remove any oxides, contaminants, or other foreign material. As is well known, bare silicon is highly reactive and readily forms a native oxide. The term “bare,” as used herein, is intended to encompass such a native oxide. A thin silicon oxide may also be intentionally grown on the semiconductor substrate, although such a grown oxide is not essential to the process in accordance with the invention.

In order to epitaxially grow a monocrystalline oxide layer overlying the monocrystalline substrate, the native oxide layer is first removed to expose the crystalline structure of the underlying substrate. The following process is generally carried out by molecular beam epitaxy (MBE), although other processes, such as those outlined below, may also be used in accordance with the present invention.

The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface.

The resultant surface, which exhibits an ordered 2×1 structure, includes strontium, oxygen, and silicon. The ordered 2×1 structure forms a template for the ordered growth of an overlying layer of a monocrystalline oxide. The template provides the chemical and physical properties to nucleate the epitaxial growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature, a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer, for example, by molecular beam epitaxy. The MBE process may be initiated by opening shutters in the MBE apparatus to expose strontium, titanium and oxygen sources. The ratio of strontium and titanium is approximately 1:1. The partial pressure of oxygen is initially set at a minimum value to facilitate the growth of stoichiometric strontium titanate at a growth rate of about 0.3-0.5 nm per minute. After initiating growth of the strontium titanate, the partial pressure of oxygen is increased above the initial minimum value.

The process described above illustrates a process for forming a semiconductor structure including a silicon substrate and an overlying oxide layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline layers such as alkaline earth metal titanates, zirconates, hafnates, tantalates, vanadates, ruthenates, and niobates, perovskite oxides such as alkaline earth metal tin-based perovskites, lanthanum aluminate, lanthanum scandium oxide, and gadolinium oxide can also be grown.

FIG. 2 illustrates schematically, in cross section, a structure 200 in accordance with an alternative embodiment of the present invention. Structure 200 may be a device such as, for example, a component for a MOS device or any high dielectric constant device. Structure 200 includes a monocrystalline semiconductor substrate 101, a monocrystalline oxide transition layer 102, a template layer 105, a monocrystalline oxide-nitride insulating layer 103, and a conductive gate electrode 104, all of which may be formed in accordance with FIG. 1 and the accompanying description. In addition, structure 200 comprises an amorphous interfacial layer 206 overlying all or a portion of substrate 101. Amorphous interfacial layer 206 generally comprises a silicon oxide or a silicon oxide-nitride material layer, either formed as a native oxide layer in accordance with the above description or deposited using any one of a variety of conventional deposition techniques. When present, amorphous interfacial layer 206 preferably has a thickness of up to about 2 nm, and serves to relieve the strain in the overlying monocrystalline oxide transition layer and/or monocrystalline oxide-nitride insulating layer, and by doing so, aids in the growth of a high crystalline quality oxide and/or oxide-nitride layers.

FIG. 3 illustrates schematically, in cross section, a semiconductor device structure 300 fabricated in accordance with one alternative embodiment of the present invention, wherein semiconductor device structure 300 comprises a MOS device. Structure 300 includes a monocrystalline semiconductor substrate 301. Substrate 301 may comprise any suitable monocrystalline semiconductor material, such as, for example, silicon (Si), germanium (Ge), silicon germanium (Si-Ge), indium phosphide (InP), or gallium arsenide (GaAs). Substrate 301 may also comprise a suitable compound semiconductor material, such as, for example, indium gallium arsenide (InGaAs), indium aluminum arsenide (InAlAs), aluminum gallium arsenide (AlGaAs), indium gallium phosphide (InGaP), and other compound semiconductor materials known to those skilled in the art to be suitable for particular semiconductor device applications. In this embodiment, substrate 301 comprises a monocrystalline silicon wafer. Substrate 101 may optionally include a plurality of material layers such that the composite substrate may be tailored to the quality, performance, and manufacturing requirements of a variety of semiconductor device applications.

Drain region 302 and source region 303 may be formed in substrate 301 using techniques well known to those skilled in the art, such as, for example, selective n-type doping via ion implantation. In one aspect of this embodiment, regions 302 and 303 are N+ doped at a concentration of at least 1E19 atoms per cubic centimeter to enable ohmic contacts to be formed. A channel region 304 is defined by a portion of substrate 301 between drain region 302 and source region 303.

In one embodiment, a template layer 305 is formed overlying substrate 301 in channel region 304. Template layer 305 may include 1-10 monolayers of silicon, oxygen, and an element suitable to successfully grow layer 306. For example, if layer 306 is formed of SrTiO₃₋ₓNₓ, where x<1.5, a suitable template layer 305 may comprise Si—O—Sr or Si—O—N—Sr.

In the embodiment of the invention illustrated in FIG. 3, a monocrystalline oxide-nitride insulating layer 306 is formed overlying template layer 305. As with layer 103 (FIG. 1), layer 306 is formed by substitutionally incorporating nitrogen into a monocrystalline oxide, such as an alkaline earth metal titanate, during formation of the insulating layer. For example, during a molecular beam epitaxy growth process of SrTiO₃ or BaTiO₃ thin films on a silicon substrate, an additional nitrogen source can be introduced simultaneously with the Sr, Ba, Ti, and oxidant sources during epitaxial growth of the layer. In one embodiment, a suitable nitrogen source may be NH₃ or N₂ and/or their radicals generated by, for example, radio frequency (rf) or electron cyclotron resonance (ECR) plasma sources. The amount of nitrogen incorporated into the oxide may be chosen such that the leakage current in the oxide film is minimized.

In an exemplary embodiment, layer 306 is formed by epitaxially growing, by a process of molecular beam epitaxy, a layer of MₙOₘ₋ₓNₓ (x<m), wherein M is a metallic or semi-metallic element or combination of metallic and/or semi-metallic elements, such as, for example, strontium (Sr), titanium (Ti), barium (Ba), aluminum (Al), erbium (Er), calcium (Ca), magnesium (Mg), tantalum (Ta), bismuth (Bi), gadolinium (Gd), zirconium (Zr), hafnium (Hf), yttrium (Y), ruthenium (Ru), lanthanum (La), gallium (Ga), indium (In), lithium (Li), sodium (Na), potassium (K), rubidium (Rb), cesium (Cs), beryllium (Be), scandium (Sc), vanadium (V), niobium (Nb), chromium (Cr), molybdenum (Mo), tungsten (W), manganese (Mn), technetium (Tc), rhenium (Re), iron (Fe), cobalt (Co), rhodium (Rh), iridium (Ir), copper (Cu), silver (Ag), gold (Au), zinc (Zn), cadmium (Cd), mercury (Hg), thallium (T1), tin (Sn), lead (Pb), antimony (Sb), bismuth (Bi), cerium (Ce), praseodymium (Pr), neodymium (Nd), samarium (Sm), europium (Eu), terbium (Tb), dysprosium (Dy), holmium (Ho), thulium (Tm), protactinium (Pa), or uranium (U).

By way of example and without limitation, exemplary materials for insulating layer 306 include the following: MO₁₋ₓNₓ (x<1), such as, for example, BaO₁₋ₓNₓ, SrO₁₋ₓNₓ, MgO₁₋ₓNₓ, CaO₁₋ₓNₓ, ZnO₁₋ₓNₓ, CdO₁₋ₓNₓ, PbO₁₋ₓNₓ, BeO₁₋ₓNₓ, and combinations thereof, MO₂₋ₓNₓ (x<2), such as, for example, ZrO₂₋ₓNₓ, TiO₂₋ₓNₓ, HfO₂₋ₓNₓ, CeO₂₋ₓNₓ, SnO₂₋ₓNₓ, PrO₂₋ₓNₓ, RuO₂₋ₓNₓ, ThO₂₋ₓNₓ, and combinations thereof, M₂O₃₋ₓNₓ (x<3), such as, for example, Al₂O₃₋ₓNₓ, Ga₂O₃₋ₓNₓ, In₂O₃₋ₓNₓ, Y₂O₃₋ₓNₓ, La₂O₃₋ₓNₓ, Sc₂O₃₋ₓNₓ, Fe₂O₃₋ₓNₓ, Gd₂O₃₋ₓNₓ, Sn₂O₃₋ₓNₓ, Bi₂O₃₋ₓNₓ, Fe₂O₃₋ₓNₓ, Pr₂O₃₋ₓNₓ, Dy₂O₃₋ₓNₓ, Ho₂O₃₋ₓNₓ, and combinations thereof, M₃O₄₋ₓNₓ (x<4), such as, for example, Fe₃O₄₋ₓNₓ, Mn₃O₄₋ₓNₓ, and combinations thereof, and M₂O₅₋ₓNₓ (x<5), such as, for example, Ta₂O₅₋ₓNₓ, Nb₂O₅₋ₓNₓ, Sb₂O₅₋ₓNₓ, and combinations thereof. Furthermore, exemplary oxide-nitride materials for insulating layer 306 may be represented empirically by the formula A₍ₙ₊₁₎BₙO₍₃ₙ₊₁₎₋ₓNₓ, wherein n is an integer and A and B are metallic and/or semi-metallic elements such as those listed above in connection with M. Such materials may include, for example: SrTiO₃₋ₓNₓ, SrZrO₃₋ₓNₓ, LaAlO₃₋ₓNₓ, and combinations thereof, wherein 0<x<3; or Sr₂TiO₄₋ₓNₓ, Sr₂ZrO₄₋ₓNₓ, La₂AlO₄₋ₓNₓ, Al₂MgO₄₋ₓNₓ, and combinations thereof, wherein 0<x<4. Alternatively, insulating layer 306 may comprise (Ba,Sr)Laₙ(Sc,Al)ₙO₍₃ₙ₊₁₎₋ₓNₓ, wherein n is an integer and x<(3n+1).

The concentration of nitrogen in layer 306 may be chosen such that the leakage current in the monocrystalline oxide film is minimized, or otherwise selected in accordance with the quality, performance, and/or manufacturing requirements of the device. In an exemplary embodiment, the concentration of nitrogen incorporated into insulating layer 306 may range from greater than 0 up to about 50 atomic percent of the total concentration of oxygen and nitrogen (i.e., x≦(m−x)). Stated another way, with regard to materials represented by the formula MₙOₘ₋ₓNₓ, it is generally preferred that the ratio (m−x):x have a value greater than or equal to about 1:1. Various relative concentrations of metal, oxygen, and nitrogen in layer 306 may be achieved by establishing different flux rates for each of the materials during epitaxial growth of the monocrystalline oxide-nitride layer. Moreover, the thickness of layer 306 may vary widely according to the desired application of the semiconductor device, but is generally in the range of about 5 to 100 nm.

In the embodiment illustrated in FIG. 3, where device 300 is a MOS device, a conductive gate electrode 307 is formed overlying insulating layer 306 in accordance with techniques well known to those skilled in the art. Gate electrode 307 may be formed of any suitable conductive material, such as, for example, platinum.

FIG. 4 illustrates schematically, in cross section, a semiconductor device structure 400 fabricated in accordance with a further alternative embodiment of the present invention, wherein semiconductor device structure 400 comprises a MOS device. Structure 400 includes a monocrystalline semiconductor substrate 401. Substrate 301 may comprise any suitable monocrystalline semiconductor material, such as, for example, silicon (Si), germanium (Ge), silicon germanium (Si-Ge), indium phosphide (InP), or gallium arsenide (GaAs). Substrate 301 may also comprise a suitable compound semiconductor material, such as, for example, indium gallium arsenide (InGaAs), indium aluminum arsenide (InAlAs), aluminum gallium arsenide (AlGaAs), indium gallium phosphide (InGaP), and other compound semiconductor materials known to those skilled in the art to be suitable for particular semiconductor device applications. In this embodiment, substrate 301 comprises a monocrystalline silicon wafer. Substrate 101 may optionally include a plurality of material layers such that the composite substrate may be tailored to the quality, performance, and manufacturing requirements of a variety of semiconductor device applications. In this embodiment, substrate 401 is a monocrystalline silicon wafer.

Drain region 402 and source region 403 are formed in substrate 401 using techniques well known to those skilled in the art, such as, for example, selective n-type doping via ion implantation. In one aspect of this embodiment, regions 402 and 403 may be N+ doped at a concentration of at least 1E19 atoms per cubic centimeter to enable ohmic contacts to be formed. A channel region 404 is defined by a portion of substrate 401 between drain region 402 and source region 403.

In this embodiment, a template layer 405 is formed overlying substrate 401 in channel region 404. Template layer 405 may be formed in accordance with the above description or in accordance with any other conventional techniques. For example, template layer 405 may include oxygen and an alkaline earth metal element suitable to successfully grow an overlying monocrystalline oxide layer, such as an alkaline earth metal titanate layer. In one aspect of an embodiment of the invention, template layer 405 is formed of 1-10 monolayers of Sr—O, Ba—O, Sr—Ba—O, Sr—O—N, Ba—O—N or Sr—Ba—O—N.

A monocrystalline oxide transition layer 406 is optionally formed overlying template layer 405 in channel region 404. Monocrystalline oxide transition layer 406, when present, may comprise a monocrystalline oxide material selected for its crystalline (i.e., lattice) compatibility with the underlying substrate, as well as with any adjacent overlying material layers. In an exemplary embodiment, layer 406 may comprise an alkaline earth metal titanate, such as, for example, barium titanate (BaTiO₃), strontium titanate (SrTiO₃), or barium strontium titanate (Sr_{z}Ba_{1-z}TiO₃, 0<z<1), or another suitable oxide material, such as, for example, LaAlO₃ or SrZrO₃. In one embodiment, layer 406 is a layer of SrTiO₃ having a thickness of up to about 1 nm.

In the embodiment of the invention illustrated in FIG. 4, a monocrystalline oxide-nitride gate dielectric layer 407 is formed overlying transition layer 406. If transition layer 406 is not present, gate dielectric layer 407 may be formed overlying substrate 401 or template layer 405. As with layer 103 (FIG. 1), layer 407 is formed by substitutionally incorporating nitrogen into a monocrystalline oxide, such as an alkaline earth metal titanate, during formation of the insulating layer. For example, during a molecular beam epitaxy growth process of SrTiO₃ or BaTiO₃ thin films on a silicon substrate, an additional nitrogen source can be used simultaneously with the Sr, Ba, Ti, and oxidant sources during epitaxial growth of the layer. In one embodiment, a suitable nitrogen source may be NH₃ or N₂ and/or their radicals generated by, for example, radio frequency (rf) or electron cyclotron resonance (ECR) plasma sources. The amount of nitrogen incorporated into the oxide may be chosen such that the leakage current in the oxide film is minimized.

In an exemplary embodiment, layer 407 may be formed by epitaxially growing by a process of molecular beam epitaxy a layer of MₙOₘ₋ₓN_{y} (x<m), wherein M is a metallic or semi-metallic element or combination of metallic and/or semi-metallic elements, such as, for example, strontium (Sr), titanium (Ti), barium (Ba), aluminum (Al), erbium (Er), calcium (Ca), magnesium (Mg), tantalum (Ta), bismuth (Bi), gadolinium (Gd), zirconium (Zr), hafnium (Hf), yttrium (Y), ruthenium (Ru), lanthanum (La), gallium (Ga), indium (In), lithium (Li), sodium (Na), potassium (K), rubidium (Rb), cesium (Cs), beryllium (Be), scandium (Sc), vanadium (V), niobium (Nb), chromium (Cr), molybdenum (Mo), tungsten (W), manganese (Mn), technetium (Tc), rhenium (Re), iron (Fe), cobalt (Co), rhodium (Rh), iridium (Ir), copper (Cu), silver (Ag), gold (Au), zinc (Zn), cadmium (Cd), mercury (Hg), thallium (TI), tin (Sn), lead (Pb), antimony (Sb), bismuth (Bi), cerium (Ce), praseodymium (Pr), neodymium (Nd), samarium (Sm), europium (Eu), terbium (Tb), dysprosium (Dy), holmium (Ho), thulium (Tm), protactinium (Pa), or uranium (U).

By way of example and without limitation, exemplary materials for gate dielectric layer 407 include the following: MO₁₋ₓNₓ (x<1), such as, for example, BaO₁₋ₓNₓ, SrO₁₋ₓNₓ, MgO₁₋ₓNₓ, CaO₁₋ₓNₓ, ZnO₁₋ₓNₓ, CdO₁₋ₓNₓ, PbO₁₋ₓNₓ, BeO₁₋ₓNₓ, and combinations thereof; MO₂₋ₓNₓ (x<2), such as, for example, ZrO₂₋ₓNₓ, TiO₂₋ₓNₓ, HfO₂₋ₓNₓ, CeO₂₋ₓNₓ, SnO₂₋ₓNₓ, PrO₂₋ₓNₓ, RuO₂₋ₓNₓ, ThO₂₋ₓNₓ, and combinations thereof; M₂O₃₋ₓNₓ (x<3), such as, for example, Al₂O₃₋ₓNₓ, Ga₂O₃₋ₓNₓ, In₂O₃₋ₓNₓ, Y₂O₃₋ₓN, La₂O₃₋ₓNₓ, Sc₂O₃₋ₓNₓ, Fe₂O₃₋ₓNₓ, Gd₂O₃₋ₓNₓ, Sn₂O₃₋ₓNₓ, Bi₂O₃₋ₓNₓ, Fe₂O₃₋ₓNₓ, Pr₂O₃₋ₓNₓ, Dy₂O₃₋ₓNₓ, Ho₂O₃₋ₓNₓ, and combinations thereof; M₃O₄₋ₓNₓ, (x<4), such as, for example, Fe₃O₄₋ₓNₓ, Mn₃O₄₋ₓNₓ, and combinations thereof; and M₂O₅₋ₓNₓ (x<5), such as, for example, Ta₂O₅₋ₓNₓ, Nb₂O₅₋ₓNₓ, Sb₂O₅₋ₓNₓ, and combinations thereof. Furthermore, exemplary oxide-nitride materials for gate dielectric layer 407 may be represented empirically by the formula A₍ₙ₊₁₎BₙO₍₃ₙ₊₁₎₋ₓNₓ, wherein n is an integer and A and B are metallic and/or semi-metallic elements such as those listed above in connection with M. Such materials may include, for example: SrTiO₃₋ₓNₓ, SrZrO₃₋ₓNₓ, LaAlO₃₋ₓNₓ, and combinations thereof, wherein 0<x<3; or Sr₂TiO₄₋ₓNₓ, Sr₂ZrO₄₋ₓNₓ, La₂AlO₄₋ₓNₓ, Al₂MgO₄₋ₓNₓ, and combinations thereof, wherein 0<x<4. Alternatively, gate dielectric layer 407 may comprise (Ba,Sr)Laₙ(Sc,Al)ₙO₍₃ₙ₊₁₎₋ₓNₓ, wherein n is an integer and x<(3n+1).

The concentration of nitrogen in layer 407 may be chosen such that the leakage current in the monocrystalline oxide film is minimized, or otherwise selected in accordance with the quality, performance, and/or manufacturing requirements of the device. In an exemplary embodiment, the concentration of nitrogen incorporated into gate dielectric layer 407 may range from greater than 0 up to about 50 atomic percent of the total concentration of oxygen and nitrogen (i.e., x<(m−x)). Stated another way, with regard to materials represented by the formula MₙOₘ₋ₓNₓ, it is generally preferred that the ratio (m−x):x have a value greater than or equal to about 1:1. Various relative concentrations of metal, oxygen, and nitrogen in layer 407 may be achieved by establishing different flux rates for each of the materials during epitaxial growth of the monocrystalline oxide-nitride layer. Moreover, the thickness of layer 407 may vary widely according to the desired application of the semiconductor device, but is generally in the range of about 5 to 100 nm.

In the embodiment illustrated in FIG. 4, where device 400 is a MOS device, a conductive gate electrode 408 may be formed overlying gate dielectric layer 407 in accordance with techniques well known to those skilled in the art. Gate electrode 408 may be formed of any suitable conductive material, such as, for example, platinum.

FIG. 5 illustrates schematically, in cross section, a structure 500 in accordance with yet another embodiment of the present invention. In this embodiment, structure 500 is a MOS device. Structure 500 includes a monocrystalline semiconductor substrate 401, a drain region 402, a source region 403, a channel region 404, a template layer 405, a monocrystalline oxide transition layer 406, a monocrystalline oxide-nitride gate dielectric insulating layer 407, and a conductive gate electrode 408, all of which may be formed in accordance with FIG. 4 and the accompanying description. In addition, structure 500 comprises an amorphous interfacial layer 509 overlying all or a portion of substrate 401. Amorphous interfacial layer 509 generally comprises a silicon oxide or a silicon oxide-nitride material layer, either formed as a native oxide layer in accordance with the above description or deposited using any one of a variety of conventional deposition techniques. When present, amorphous interfacial layer 509 preferably has a thickness of up to about 2 nm, and serves to relieve the strain in the overlying monocrystalline oxide transition layer and/or monocrystalline oxide-nitride insulating layer, and by doing so, aids in the growth of a high crystalline quality oxide and/or oxide-nitride layers.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. Further, no element described herein is essential to the practice of the invention unless expressly described as “essential” or “required.”

1. A semiconductor device structure comprising:
a monocrystalline semiconductor substrate; and
an insulating layer overlying said substrate, said insulating layer comprising MₙOₘ₋ₓNₓ wherein M is a metallic or semi-metallic element or combination of metallic and/or semi-metallic elements, m and n are integers, and x<m.

2. The structure of claim 1 wherein said insulating layer comprises MO₁₋ₓNₓ, where M is an element or a combination of elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, TI, Sn, Pb, Sb, Bi, Ce, Pr, Nd, Sm, Eu, Gd, Tb, Dy, Ho, Er, Tm, Yb, Lu, Th, Pa, and U.

3. The structure of claim 1 wherein said insulating layer comprises MO_{2 -x}Nₓ, where M is an element or a combination of elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, TI, Sn, Pb, Sb, Bi, Ce, Pr, Nd, Sm, Eu, Gd, Tb, Dy, Ho, Er, Tm, Yb, Lu, Th, Pa, and U.

4. The structure of claim 1 wherein said insulating layer comprises M₂O₃₋ₓNₓ, where M is an element or a combination of elements selected from the group consisting of Li, Na, K, Rb, Cs, Be, Mg, Ca, Sr, Ba, Sc, Y, La, Ti, Zr, Hf. V, Nb, Ta, Cr, Mo, W, Mn, Tc, Re, Fe, Ru, Co, Rh, Ir, Cu, Ag, Au, Zn, Cd, Hg, Al, Ga, In, Tl, Sn, Pb, Sb, Bi, Ce, Pr, Nd, Sm, Eu, Gd, Tb, Dy, Ho, Er, Tm, Yb, Lu, Th, Pa, and U.

5. The structure of claim 1 wherein said insulating layer comprises M₃O₄₋ₓNₓ, where M is an element or a combination of elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, Tl, Sn, Pb, Sb, Bi, Ce, Pr, Nd, Sm, Eu, Gd, Tb, Dy, Ho, Er, Tm, Yb, Lu, Th, Pa, and U.

6. The structure of claim 1 wherein said insulating layer comprises M₂O₅₋ₓNₓ, where M is an element or a combination of elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, Tl, Sn, Pb, Sb, Bi, Ce, Pr, Nd, Sm, Eu, Gd, Tb, Dy, Ho, Er, Tm, Yb, Lu, Th, Pa, and U.

7. The structure of claim 1 wherein said insulating layer comprises A₍ₙ₊₁₎BₙO₍₃ₙ₊₁₎₋ₓNₓ, wherein n is an integer and A and B are elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, Tl, Sn, Pb, Sb, Bi, Ce, Pr, Nd, Sm, Eu, Gd, Tb, Dy, Ho, Er, Tm, Yb, Lu, Th, Pa, and U.

8. The structure of claim 1 wherein said insulating layer comprises (Ba,Sr)La,(Sc,Al)ₙO₍₃ₙ₊₁₎₋ₓNₓ, wherein n is an integer and x<(3n+1).

9. The structure of claim 1 wherein said insulating layer comprises a material selected from the group comprising ZrO₂₋ₓNₓ, TiO₂₋ₓNₓ, HfO₂₋ₓNₓ, CeO₂₋ₓNₓ, SnO₂₋ₓNₓ, PrO₂₋ₓNₓ, RuO₂₋ₓNₓ, ThO₂₋ₓNₓ, and combinations thereof.

10. The structure of claim 1 wherein said insulating layer comprises a material selected from the group comprising BaO₁₋ₓNₓ, SrO₁₋ₓNₓ, MgO₁₋ₓNₓ, CaO₁₋ₓNₓ, ZnO₁₋ₓNₓ, CdO₁₋ₓNₓ, PbO₁₋ₓNₓ, BeO₁₋ₓNₓ, and combinations thereof.

11. The structure of claim 1 wherein said insulating layer comprises a material selected from the group comprising Al₂O₃₋ₓNₓ, Ga₂O₃₋ₓNₓ, In₂O₃₋ₓNₓ, Y₂O₃₋ₓNₓ, La₂O₃₋ₓNₓ, Sc₂O₃₋ₓNₓ, Fe₂O₃₋ₓNₓ, Gd₂O₃₋ₓNₓ, Sn₂O₃₋ₓNₓ, Bi₂O₃₋ₓNₓ, Fe₂O₃₋ₓNₓ, Pr₂O₃₋ₓNₓ, Dy₂O₃₋ₓNₓ, Ho₂O₃₋ₓNₓ, and combinations thereof.

12. The structure of claim 1 wherein said insulating layer comprises a material selected from the group comprising Fe₃O₄₋ₓNₓ, Mn₃O₄₋ₓNₓ, and combinations thereof.

13. The structure of claim 1 wherein said insulating layer comprises a material selected from the group comprising Ta₂O₅₋ₓNₓ, Nb₂O₅₋ₓNₓ, Sb₂O₅₋ₓNₓ, and combinations thereof.

14. The structure of claim 1 wherein said insulating layer comprises a material selected from the group consisting of SrTiO₃₋ₓNₓ, SrZrO₃₋ₓNₓ, LaAlO₃₋ₓNₓ, and combinations thereof, where 0<x<3.

15. The structure of claim 1 wherein said insulating layer comprises a material selected from the group consisting of Sr₂TiO₄₋ₓNₓ, Sr₂ZrO₄₋ₓNₓ, La₂AlO₄₋ₓNₓ, Al₂MgO₄₋ₓNₓ, and combinations thereof, where 0<x<4.

16. The structure of claim 1 further comprising a monocrystalline transition layer comprising an alkaline earth metal titanate underlying the insulating layer.

17. The structure of claim 3 wherein said monocrystalline transition layer comprises a material selected from the group consisting of SrTiO₃, BaSrTiO₃, BaTiO₃, SrZrO₃, and LaAlO₃.

18. The structure of claim 16 wherein said monocrystalline transition layer has a thickness of up to about 1 nm.

19. The structure of claim 1 further comprising a conductive electrode formed overlying said insulating layer.

20. The structure of claim 19 further comprising an electrically conductive region formed in said substrate.

21. The structure of claim 1 wherein said monocrystalline semiconductor substrate comprises a semiconductor material selected from the group consisting of Si, Ge, Si—Ge, InP and GaAs.

22. The structure of claim 1 wherein said monocrystalline semiconductor substrate comprises a layer of semiconductor material selected from the group consisting of InGaAs, InAlAs, AlGaAs, and InGaP.

23. The structure of claim 1 wherein the ratio (m−x):x is greater than or equal to about 1:1.

24. The structure of claim 1 further comprising a template layer overlying said monocrystalline semiconductor substrate.

25. The structure of claim 24 wherein said template layer comprises 1-10 monolayers comprising oxygen and an alkaline earth metal element.

26. The structure of claim 24 wherein said template layer comprises 1-10 monolayers comprising oxygen, nitrogen, and an alkaline earth metal element.

27. The structure of claim 1 further comprising an amorphous interfacial layer overlying at least a portion of said substrate.

28. The structure of claim 27 wherein said amorphous interfacial layer comprises at least one of Si—O and Si—O—N, and wherein said amorphous interfacial layer has a thickness of up to about 2 nm.

29. A semiconductor device structure comprising:
a monocrystalline semiconductor substrate; and
a monocrystalline oxide-nitride layer epitaxially grown overlying said substrate, said monocrystalline oxide-nitride layer comprising MₙOₘ₋ₓNₓ, wherein M is a metallic or semi-metallic element or combination of metallic and/or semi-metallic elements, m and n are integers, and x<m.

30. The structure of claim 29 wherein said monocrystalline oxide-nitride layer comprises MO₁₋ₓNₓ, where M is an element or a combination of elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, Ti, Sn, Pb, Sb, Bi, Ce, Pr, Nd, Sm, Eu, Gd, Tb, Dy, Ho, Er, Tm, Yb, Lu, Th, Pa, and U.

31. The structure of claim 29 wherein said monocrystalline oxide-nitride layer comprises MO₂₋ₓNₓ, where M is an element or a combination of elements selected from the group consisting of Li, Na, K, Rb, Cs, Be, Mg, Ca, Sr, Ba, Sc, Y, La, Ti, Zr, Hf. V, Nb, Ta, Cr, Mo, W, Mn, Tc, Re, Fe, Ru, Co, Rh, Ir, Cu, Ag, Au, Zn, Cd, Hg, Al, Ga, In, TI, Sn, Pb, Sb, Bi, Ce, Pr, Nd, Sm, Eu, Gd, Tb, Dy, Ho, Er, Tm, Yb, Lu, Th, Pa, and U.

32. The structure of claim 29 wherein said monocrystalline oxide-nitride layer comprises M₂O₃₋ₓNₓ, where M is an element or a combination of elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, TI, Sn, Pb, Sb, Bi, Ce, Pr, Nd, Sm, Eu, Gd, Tb, Dy, Ho, Er, Tm, Yb, Lu, Th, Pa, and U.

33. The structure of claim 29 wherein said monocrystalline oxide-nitride layer comprises M₃O₄₋ₓNₓ, where M is an element or a combination of elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, Ti, Sn, Pb, Sb, Bi, Ce, Pr, Nd, Sm, Eu, Gd, Tb, Dy, Ho, Er, Tm, Yb, Lu, Th, Pa, and U.

34. The structure of claim 29 wherein said monocrystalline oxide-nitride layer comprises M₂O₅₋ₓNₓ, where M is an element or a combination of elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Ir, Cu, Ag, Au, Zn, Cd, Hg, Al, Ga, In, Tl, Sn, Pb, Sb, Bi, Ce, Pr, Nd, Sm, Eu, Gd, Tb, Dy, Ho, Er, Tm, Yb, Lu, Th, Pa, and U.

35. The structure of claim 29 wherein said monocrystalline oxide-nitride layer comprises A₍ₙ₊₁₎BₙO₍₃ₙ₊₁₎₋ₓNₓ, wherein A and B are elements selected from the group consisting of Li, Na, K, Rb, Cs, Be, Mg, Ca, Sr, Ba, Sc, Y, La, Ti, Zr, Hf, V, Nb, Ta, Cr, Mo, W, Mn, Tc, Re, Fe, Ru, Co, Rh, Jr, Cu, Ag, Au, Zn, Cd, Hg, Al, Ga, In, Tl, Sn, Pb, Sb, Bi, Ce, Pr, Nd, Sm, Eu, Gd, Tb, Dy, Ho, Er, Tm, Yb, Lu, Th, Pa, and U.

36. The structure of claim 29 wherein said monocrystalline oxide-nitride layer comprises (Ba,Sr)Laₙ(Sc,Al)ₙO₍₃ₙ₊₁₎₋ₓNₓ, wherein n is an integer and x<(3n+1).

37. The structure of claim 29 wherein said monocrystalline oxide-nitride layer comprises a material selected from the group comprising ZrO₂₋ₓNₓ, TiO₂₋ₓNₓ, HfO₂₋ₓNₓ, CeO₂₋ₓNₓ, SnO₂₋ₓNₓ, PrO₂₋ₓNₓ, RuO₂₋ₓNₓ, ThO₂₋ₓNₓ, and combinations thereof.

38. The structure of claim 29 wherein said monocrystalline oxide-nitride layer comprises a material selected from the group comprising BaO₁₋ₓNₓ, SrO₁₋ₓNₓ, MgO₁₋ₓNₓ, CaO₁₋ₓNₓ, ZnO₁₋ₓNₓ, CdO₁₋ₓNₓ, PbO₁₋ₓNₓ, BeO₁₋ₓNₓ, and combinations thereof.

39. The structure of claim 29 wherein said monocrystalline oxide-nitride layer comprises a material selected from the group comprising Al₂O₃₋ₓNₓ, Ga₂O₃₋ₓNₓ, In₂O₃₋ₓNₓ, Y₂O₃₋ₓNₓ, La₂O₃₋ₓNₓ, Sc₂O₃₋ₓNₓ, Fe₂O₃₋ₓNₓ, Gd₂O₃₋ₓNₓ, Sn₂O₃₋ₓNₓ, Bi₂O₃₋ₓNₓ, Fe₂O₃₋ₓNₓ, Pr₂O₃₋ₓNₓ, Dy₂O₃₋ₓNₓ, Ho₂O₃₋ₓNₓ, and combinations thereof.

40. The structure of claim 29 wherein said monocrystalline oxide-nitride layer comprises a material selected from the group comprising Fe₃O₄₋ₓNₓ, Mn₃O₄₋ₓNₓ, and combinations thereof.

41. The structure of claim 29 wherein said monocrystalline oxide-nitride layer comprises a material selected from the group comprising Ta₂O₅₋ₓNₓ, Nb₂O₅₋ₓNₓ, Sb₂O₅₋ₓNₓ, and combinations thereof.

42. The structure of claim 29 wherein said monocrystalline oxide-nitride layer comprises a material selected from the group consisting of SrTiO₃₋ₓNₓ, SrZrO₃₋ₓNₓ, LaAlO₃₋ₓNₓ, and combinations thereof, where 0<x<3.

43. The structure of claim 29 wherein said monocrystalline oxide-nitride layer comprises a material selected from the group consisting of Sr₂TiO₄₋ₓNₓ, Sr₂ZrO₄₋ₓNₓ, La₂AlO₄₋ₓNₓ, Al₂MgO₄₋ₓNₓ, and combinations thereof, where 0<x<4.

44. The structure of claim 29 further comprising a monocrystalline transition layer comprising an alkaline earth metal titanate underlying said monocrystalline oxide-nitride layer.

45. The structure of claim 44 wherein said monocrystalline transition layer comprises a material selected from the group consisting of SrTiO₃, BaSrTiO₃, BaTiO₃, SrZrO₃, and LaAlO₃.

46. The structure of claim 44 wherein said monocrystalline transition layer has a thickness of up to about 1 nm.

47. The structure of claim 29 further comprising a conductive electrode formed overlying said monocrystalline oxide-nitride layer.

48. The structure of claim 47 further comprising an electrically conductive region formed in said substrate.

49. The structure of claim 29 wherein said monocrystalline semiconductor substrate comprises a semiconductor material selected from the group consisting of Si, Ge, Si—Ge, InP and GaAs.

50. The structure of claim 29 wherein said monocrystalline semiconductor substrate comprises a layer of semiconductor material selected from the group consisting of InGaAs, InAlAs, AlGaAs, and InGaP.

51. The structure of claim 29 wherein the ratio (m−x):x is greater than or equal to about 1:1.

52. The structure of claim 29 wherein said monocrystalline oxide-nitride layer comprises a material selected from the group consisting of SrTiO₃₋ₓNₓ and LaAlO₃₋ₓNₓ, where 0<x<3.

53. The device structure of claim 29 further comprising a platinum electrode overlying said monocrystalline oxide-nitride layer.

54. The device structure of claim 29 further comprising a monocrystalline transition layer underlying said monocrystalline oxide-nitride layer, said transition layer comprising an alkaline earth metal titanate.

55. The structure of claim 29 further comprising a template layer overlying said monocrystalline semiconductor substrate.

56. The structure of claim 55 wherein said template layer comprises 1-10 monolayers comprising oxygen and an alkaline earth metal element.

57. The structure of claim 55 wherein said template layer comprises 1-10 monolayers comprising oxygen, nitrogen, and an alkaline earth metal element.

58. The structure of claim 29 further comprising an amorphous interfacial layer overlying at least a portion of said substrate.

59. The structure of claim 58 wherein said amorphous interfacial layer comprises at least one of Si—O and Si—O—N, and wherein said amorphous interfacial layer has a thickness of up to about 2 nm.

60. A semiconductor device structure comprising:
a monocrystalline semiconductor substrate;
source, drain, and channel regions of a MOS transistor formed in said substrate;
a monocrystalline gate dielectric epitaxially formed overlying said channel region, said gate dielectric comprising MₙOₘ₋ₓNₓ, wherein M is a metallic or semi-metallic element or combination of metallic and/or semi-metallic elements, m and n are integers, x<m, and the ratio (m−x):x is greater than or equal to about 1:1; and
a gate electrode overlying said gate dielectric.

61. The structure of claim 60 wherein said gate dielectric comprises a material selected from the group consisting of SrTiO₃₋ₓNₓ, SrZrO₃₋ₓNₓ, LaAlO₃₋ₓNₓ, and combinations thereof, where 0<x<3.

62. The structure of claim 60 wherein said gate dielectric comprises a material selected from the group consisting of Sr₂TiO₄₋ₓNₓ, Sr₂ZrO₄₋ₓNₓ, La₂AlO₄₋ₓNₓ, Al₂MgO₄₋ₓNₓ, and combinations thereof, where 0<x<4.

63. The structure of claim 60 further comprising a monocrystalline transition layer comprising an alkaline earth metal titanate underlying said gate dielectric.

64. The structure of claim 63 wherein said monocrystalline transition layer comprises a material selected from the group consisting of SrTiO₃, BaSrTiO₃, BaTiO₃, SrZrO₃, and LaAlO₃.

65. The structure of claim 63 wherein said monocrystalline transition layer has a thickness of up to about 1 nm.

66. A process for fabricating a semiconductor device structure comprising the steps of:
providing a monocrystalline semiconductor substrate;
epitaxially growing, by a process selected from the group consisting of molecular beam epitaxy, chemical vapor deposition, metal organic chemical vapor deposition, migration enhanced epitaxy, atomic layer epitaxy, physical vapor deposition, chemical solution deposition, and pulsed laser deposition, an insulating layer comprising a monocrystalline alkaline earth metal titanate overlying said substrate; and
during the step of epitaxially growing, incorporating nitrogen into said insulating layer.

67. The process of claim 66 wherein said step of incorporating comprises incorporating nitrogen at a concentration greater than 0 and up to about 50 atomic percent of the total concentration of oxygen and nitrogen in said insulating layer.

68. The process of claim 66 wherein said step of incorporating is initiated after growing a transition layer of monocrystalline alkaline earth metal titanate without any incorporated nitrogen.

69. The process of claim 66 further comprising the step of forming an electrically conductive region in said substrate.

70. The process of claim 66 further comprising the step of depositing a conductive electrode overlying said insulating layer.

71. The process of claim 66 wherein said step of providing a semiconductor substrate comprises providing a substrate comprising a bulk substrate selected from the group consisting of Si, Ge, Si—Ge, InP and GaAs.

72. The process of claim 66 wherein said step of providing a semiconductor substrate comprises providing a substrate comprising a layer of semiconductor material selected from the group consisting of InGaAs, InAlAs, AlGaAs, and InGaP.

73. The process of claim 66 further comprising the step of forming a template layer on said semiconductor substrate prior to the step of epitaxially growing.

74. The process of claim 66 wherein said step of forming a template layer comprises depositing 1-10 monolayers comprising oxygen and an alkaline earth metal element.

75. The process of claim 66 wherein said step of forming a template layer comprises depositing 1-10 monolayers comprising oxygen, nitrogen, and an alkaline earth metal element.

76. A process for fabricating a device structure comprising the steps of:
providing a monocrystalline silicon substrate;
forming a MOS device at least partially in said substrate;
epitaxially growing, by a process of molecular beam epitaxy, a monocrystalline gate dielectric insulating layer comprising MₙOₘ₋ₓNₓ wherein M is a metallic or semi-metallic element or combination of metallic and/or semi-metallic elements, m and n are integers, x<m, and the ratio (m−x):x is greater than or equal to about 1:1, said gate dielectric insulating layer overlying said MOS device; and
depositing by physical vapor deposition a gate electrode overlying said gate dielectric insulating layer.

77. The process of claim 76 further comprising the step of forming a template layer on said substrate prior to the step of epitaxially growing.

78. The process of claim 77 wherein said step of forming a template layer comprises forming 1-10 monolayers comprising oxygen and an alkaline earth metal element.

79. The process of claim 77 wherein said step of forming a template layer comprises depositing 1-10 monolayers comprising oxygen, nitrogen, and an alkaline earth metal element.

80. The process of claim 76 further comprising the step of forming an amorphous interfacial layer overlying at least a portion of said substrate.

81. The process of claim 80 wherein said step of forming an amorphous interfacial layer comprises forming an amorphous interfacial layer comprising at least one of Si—O and Si—O—N, and wherein said amorphous interfacial layer has a thickness of up to about 2 nm.

82. The process of claim 76 further comprising the step of epitaxially growing, by a process of molecular beam epitaxy, a monocrystalline transition layer underlying said gate dielectric layer, said monocrystalline transition layer comprising a material selected from the group consisting of SrTiO₃, BaSrTiO₃, BaTiO₃, SrZrO₃, and LaAlO₃.

83. The process of claim 76 wherein said step of epitaxially growing comprises epitaxially growing a gate dielectric layer comprising (Ba,Sr)TiO₃ and incorporating nitrogen into said gate dielectric layer to a concentration up to about 50 atomic percent of the total concentration of oxygen and nitrogen in said gate dielectric layer.
